(19) United States
(12) Patent Application Publication
(10) Pub. No.: US 2022/0412676 A1
(43) Pub. Date: Dec. 29, 2022

(54) HEAT DISSIPATION MEMBER AND HEAT SINK

(71) Applicant: Mitsubishi Electric Corporation, Tokyo (JP)

(72) Inventors: Motoki MASAKI, Tokyo (JP); Shinya TOKIZAKI, Tokyo (JP)

(73) Assignee: Mitsubishi Electric Corporation, Tokyo (JP)

(21) Appl. No.: 17/777,622

(22) PCT Filed: Jan. 21, 2020
(86) PCT No.: PCT/JP2020/001987

§ 371 Date: May 18, 2022

(51) Int. Cl. F28F 13/18; F28F 21/04

(52) U.S. Cl. CPC F28F 13/18; F28F 21/04; F28F 2245/06

(57) ABSTRACT

A heat dissipation member includes a thermal radiation ceramic material, and the thermal radiation ceramic material contains silicon nitride and boron nitride as main components. The ratio of the mass of boron nitride to the mass of silicon nitride and boron nitride is 10 mass % to 40 mass %.

### FIELD

The present disclosure relates to a heat dissipation member and a heat sink for use in heat dissipation of electrical and electronic devices.

### BACKGROUND

In electrical/electronic devices equipped with heat generating components such as light emitting diode (LED) elements or integrated circuits (ICs), heat dissipation techniques based on either natural air cooling with aluminum heat sinks or forced air cooling with electric fans are usually used. It is difficult to apply aluminum heat sinks or electric fans that require air convection to in-vehicle electrical equipment used in sealed housings for dustproof and waterproof purposes or to space equipment used in vacuum. Regarding information equipment including laptop personal computers that tend to generate an increasing amount of heat as the performance of central processing units (CPUs) increases, the progress of miniaturization and high-density mounting has made it difficult to secure a space for storing an aluminum heat sink having a large volume. Furthermore, aluminum heat sinks, which are made of metal, generate electromagnetic noise that may cause the electrical/electronic devices to malfunction. Thus, the conventional heat dissipation techniques based on aluminum heat sinks or electric fans are difficult to apply as heat dissipation measures to some types of electrical/electronic devices, for which ceramic heat sinks based on heat radiation of infrared have attracted attention.

Patent Literature 1 discloses a magnetic memory device in which a heat dissipation member is provided in contact with a surface of a sealant with which a magnetic random access memory is sealed. Patent Literature 1 discloses that the heat dissipation member is made of a metal having good thermal conductivity or a high thermal conductive ceramic. The high thermal conductive ceramic is exemplified by aluminum oxide, aluminum nitride, boron nitride, silicon nitride, or silicon carbide.

### CITATION LIST

### Patent Literature

Patent Literature 1: Japanese Patent Application Laid-open No. 2005-78693

### SUMMARY

### Technical Problem

The emissivity of a ceramic material is determined by the radiation spectrum unique to the crystal structure of each substance, and there are a wavelength region with high emissivity and a wavelength region with low emissivity. Therefore, in general, it is difficult with a single ceramic material to increase the average emissivity, i.e. average of the emissivity in all wavelength regions of infrared. That is, with the technique described in Patent Literature 1, in which aluminum oxide, aluminum nitride, boron nitride, silicon nitride, or silicon carbide is used alone as the high thermal conductive ceramic, it is difficult to further improve the average emissivity in infrared regions.

The present disclosure has been made in view of the above, and an object thereof is to obtain a heat dissipation member with a better average emissivity in infrared regions than the conventional ones.

### Solution to Problem

In order to solve the above-described problems and achieve the object, a heat dissipation member according to the present disclosure includes a thermal radiation ceramic material, and the thermal radiation ceramic material contains silicon nitride and boron nitride as main components. The ratio of the mass of boron nitride to the mass of silicon nitride and boron nitride is 10 mass % to 40 mass %.

### Advantageous Effects of Invention

The present disclosure is advantageous in achieving a better average emissivity in infrared regions than the conventional ones.

### BRIEF DESCRIPTION OF DRAWINGS

FIG. 1 is a cross-sectional view schematically illustrating an exemplary configuration of an electrical/electronic device including a heat dissipation member according to a first embodiment.

FIG. 2 is a cross-sectional view schematically illustrating an exemplary configuration of the heat dissipation member according to the first embodiment.

FIG. 3 is a cross-sectional view schematically illustrating another exemplary configuration of the heat dissipation member according to the first embodiment.

FIG. 4 is a cross-sectional view schematically illustrating an exemplary configuration of a heat dissipation member according to a second embodiment.

FIG. 5 is a diagram illustrating examples of the raw materials, thermal radiation ceramic materials, and characteristics of the heat dissipation members according to Examples 1 to 8 and Comparative Examples 1 to 3.

### DESCRIPTION OF EMBODIMENTS

Hereinafter, a heat dissipation member and a heat sink according to embodiments of the present disclosure will be described in detail with reference to the drawings. The present disclosure is not limited to the embodiments.

### First Embodiment

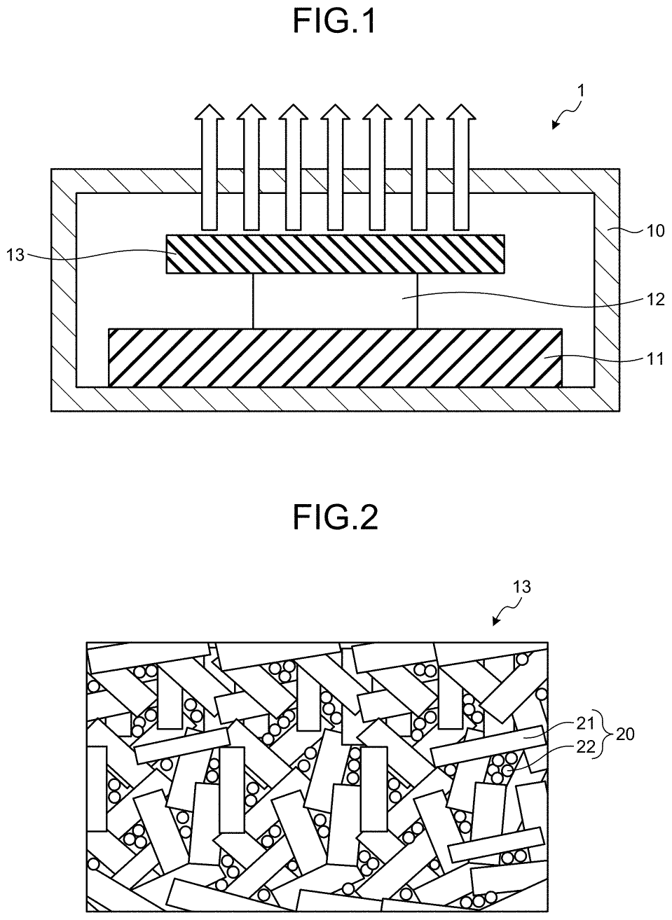

FIG. 1 is a cross-sectional view schematically illustrating an exemplary configuration of an electrical/electronic device including a heat dissipation member according to the first embodiment. The electrical/electronic device 1 is an electrical device or an electronic device equipped with a heat generating component such as an LED element or an IC. The electrical/electronic device 1 includes a housing 10 containing a substrate 11 and components located on the substrate 11. In one example, the housing 10 encloses the substrate 11 located therein for dustproof and waterproof purposes. In one example, the substrate 11 is a printed-wiring board. The components are a circuit component connected onto the substrate 11 via solder, a semiconductor package including a semiconductor element, and the like. Some components generate heat by operation. Hereinafter, a component that generates heat is referred to as a heat generating component 12.

The electrical/electronic device 1 further includes a heat dissipation member 13 located in contact with the heat generating component 12 in the housing 10. The heat dissipation member 13 is a member that radiates heat from the heat generating component 12 using heat radiation of infrared. Examples of a cooling device that uses the heat dissipation member 13 include a heat sink, a heat spreader, and a heat dissipation substrate. That is, the heat sink, the heat spreader, and the heat dissipation substrate include the heat dissipation member 13. Details of the heat dissipation member 13 will be described later.

FIG. 2 is a cross-sectional view schematically illustrating an exemplary configuration of the heat dissipation member according to the first embodiment. The heat dissipation member 13 includes a sintered body of a thermal radiation ceramic material 20. The heat dissipation member 13 including the thermal radiation ceramic material 20 exerts a cooling effect by releasing heat generated from a heat source such as a semiconductor element included in the heat generating component 12 to the outside through infrared radiation. Therefore, the thermal radiation ceramic material 20 preferably has as high an emissivity as possible. However, the emissivity of a ceramic material is determined by the radiation spectrum unique to the crystal structure of each substance, and there are a wavelength region with high emissivity and a wavelength region with low emissivity. Therefore, in general, it is difficult with a single ceramic material to increase the average emissivity, i.e. average of the emissivity in all wavelength regions of infrared. In view of this, the heat dissipation member 13 in the first embodiment includes the thermal radiation ceramic material (Si₃N₄—BN) 20 that is a sintered body obtained by compounding silicon nitride (Si₃N₄) particles 21 and boron nitride (BN) particles 22 having different radiation spectra. Consequently, a relatively high thermal emissivity can be obtained, and a high average emissivity can be achieved in the infrared regions having a wavelength of 3 μm to 25 μm. Here, the term “average emissivity” refers to the average of the emissivity in the infrared regions having a wavelength of 3 μm to 25 μm.

In the first embodiment, the ratio of the mass of the boron nitride particles 22 to the mass of the silicon nitride particles 21 and the boron nitride particles 22 of the thermal radiation ceramic material 20 constituting the heat dissipation member 13, that is, the ratio of the mass of boron nitride to the mass of silicon nitride and boron nitride, is 10 mass % to 40 mass %. Hereinafter, the ratio of the mass of the boron nitride particles 22 to the mass of the silicon nitride particles 21 and the boron nitride particles 22 is also simply referred to as the ratio of the mass of the boron nitride particles 22. The ratio of the mass of the boron nitride particles 22 is preferably 20 mass % to 30 mass %.

When the ratio of the mass of the boron nitride particles 22 is too low, that is, when the ratio of the mass of the boron nitride particles 22 is lower than 10 mass %, there is a wavelength region with low emissivity which results in unimproved average emissivity. That is, when the thermal radiation ceramic material 20 having such a mass ratio of the silicon nitride particles 21 and the boron nitride particles 22 is used as the heat dissipation member 13, sufficient cooling performance cannot be obtained. Therefore, the ratio of the mass of the boron nitride particles 22 is desirably higher than or equal to 10 mass %.

On the other hand, when the ratio of the mass of the boron nitride particles 22 is too high, that is, when the ratio of the mass of the boron nitride particles 22 is higher than 40 mass %, the thermal radiation ceramic material 20 has a high porosity which extremely lowers the thermal conductivity. That is, the heat generated from the heat generating component 12 as a heat source is less likely to be transferred to the heat dissipation member 13, which hinders improvement in cooling performance. In addition, the mechanical strength of the thermal radiation ceramic material 20 is significantly reduced. Therefore, when the thermal radiation ceramic material 20 having such a mass ratio of the silicon nitride particles 21 and the boron nitride particles 22 is used as the heat dissipation member 13, fractures or cracks may occur. Therefore, the ratio of the mass of the boron nitride particles 22 is desirably lower than or equal to 40 mass %. When the ratio of the mass of the boron nitride particles 22 is 20 mass % to 30 mass %, both the emissivity and the thermal conductivity related to the cooling performance of the heat dissipation member 13 are further improved.

The boron nitride particles 22 contained in the thermal radiation ceramic material 20 may be turbostratic boron nitride (t-BN) in which hexagonal BN layers are randomly stacked, but is preferably hexagonal boron nitride (h-BN) in which hexagonal BN layers are regularly stacked. By containing hexagonal boron nitride, the thermal radiation ceramic material 20 is likely to have improved thermal conductivity and improved average thermal emissivity.

The porosity of the thermal radiation ceramic material 20 is related to the thermal conductivity and mechanical strength of the heat dissipation member 13. That is, when the porosity of the thermal radiation ceramic material 20 is too high, voids are connected to each other inside the thermal radiation ceramic material 20, resulting in a decrease in mechanical strength. In addition, the air layers in voids serve as a heat insulator that hinders heat transfer, which results in reduced thermal conductivity. Therefore, from the viewpoint of obtaining desired thermal conductivity and mechanical strength, the porosity of the thermal radiation ceramic material 20 is preferably lower than or equal to 40%. The porosity of the thermal radiation ceramic material 20 is more preferably lower than or equal to 35%, and still more preferably lower than or equal to 30%.

The porosity of the thermal radiation ceramic material 20 tends to decrease as the ratio of the mass of the boron nitride particles 22 decreases. However, as described above, when the ratio of the mass of the boron nitride particles 22 is lower than 10 mass %, the average emissivity of the thermal radiation ceramic material 20 is not improved. When the ratio of the mass of the boron nitride particles 22 is lower than 10 mass %, the porosity is also lower than 10%. In consideration of these, the porosity of the thermal radiation ceramic material 20 is desirably 10% to 40%.

The “porosity” of the thermal radiation ceramic material 20 as used herein will now be described. The “porosity” is calculated according to Archimedes' principle. Specifically, the “porosity” can be calculated from Formula (1) below using the measured values of the mass and dimensions of the thermal radiation ceramic material 20 cut out into a rectangular parallelepiped shape. Note that the dimensions of the thermal radiation ceramic material 20 having a rectangular parallelepiped shape are length, width, and height.

Porosity={1−[W_{dry}/(L×W×T)/ρ_{theory}]}×100 (1)

In Formula (1), W_{dry} is the mass (g) of the thermal radiation ceramic material 20 that has been dried at 150° C. for 2 hours. In Formula (1), L, W, and T are respectively the length, width, and height (cm) of the thermal radiation ceramic material 20 having a rectangular parallelepiped shape, and ρ_{theory} is the theoretical density (g/cm³) of the thermal radiation ceramic material 20.

The average emissivity of the thermal radiation ceramic material 20 is higher than or equal to 70%. In general, the emissivity of the thermal radiation ceramic material 20 varies with temperature, but the thermal radiation ceramic material 20 that has an average emissivity of 70% or higher in the temperature region up to 200° C., preferably the temperature region up to 150° C., in which the heat dissipation member 13 of the electrical/electronic device 1 is usually used, can achieve sufficient cooling performance as the heat dissipation member 13. Furthermore, the thermal conductivity of the thermal radiation ceramic material 20 is preferably higher than or equal to 40 W/(m·K). This is because when the thermal conductivity is 40 W/(m·K) or higher, heat generated from the heat source is efficiently transferred to the heat dissipation member 13, so that much higher cooling performance can be expected.

The silicon nitride and boron nitride contained in the thermal radiation ceramic material 20 are present as particles. From the viewpoint of uniformizing the cooling performance of the thermal radiation ceramic material 20 and improving the mechanical strength, the boron nitride particles 22 are preferably dispersed uniformly between the silicon nitride particles 21.

From the viewpoint of ensuring that the boron nitride particles 22 are uniformly dispersed, the average particle size of the boron nitride particles 22 is desirably 0.05 μm to 1 μm.

If the average particle size of the boron nitride particles 22 exceeds 1 μm, it may be difficult to obtain a state in which the boron nitride particles 22 are uniformly dispersed between the silicon nitride particles 21. On the other hand, if the average particle size of the boron nitride particles 22 is less than 0.05 μm, the boron nitride particles 22 may form a strong aggregation that makes it difficult to obtain a state in which the boron nitride particles 22 are uniformly dispersed between the silicon nitride particles 21. As a result, portions having many boron nitride particles 22 and portions having many silicon nitride particles 21 are non-uniformly generated inside the thermal radiation ceramic material 20. Hereinafter, portions having many boron nitride particles 22 are referred to as boron-nitride-rich portions, and portions having many silicon nitride particles 21 are referred to as silicon-nitride-rich portions. Such non-uniformity causes non-uniformity in the cooling performance of the heat dissipation member 13. In addition, boron-nitride-rich portions have a high porosity, which reduces the mechanical strength and causes fractures and cracks. Therefore, if the boron nitride particles 22 are not uniformly dispersed between the silicon nitride particles 21, the cooling performance and the mechanical strength of the whole heat dissipation member 13 including the thermal radiation ceramic material 20 tend not to be sufficiently improved. Thus, the average particle size of the boron nitride particles 22 is desirably 0.05 μm to 1 μm.

The average particle size of the silicon nitride particles 21 is not particularly limited, but is desirably 2 μm to 30 μm.

Here, the average particle size of the particles in the thermal radiation ceramic material 20 can be obtained by observing a cross-section of the thermal radiation ceramic material 20 with a scanning electron microscope (SEM). Specifically, the average particle size of the particles can be obtained by cutting the thermal radiation ceramic material 20, magnifying the cross-section thereof, for example, 15,000 times with the SEM, measuring the major axis diameters of at least 20 particles, and averaging the measured values.

In addition to the silicon nitride particles 21 and the boron nitride particles 22, the thermal radiation ceramic material 20 may contain a sintering aid for densification. The sintering aid is not particularly limited, and those known in the art can be used. Examples of the sintering aid include oxides of rare-earth elements such as yttrium, oxides of aluminum, titanium, magnesium, or silicon, and nitrides of aluminum or titanium. These can be used alone or in combination of two or more. Among them, an oxide of a rare-earth element is preferably used as the sintering aid from the viewpoint of the average emissivity and the mechanical strength of the thermal radiation ceramic material 20.

The amount of sintering aid contained in the thermal radiation ceramic material 20 is not particularly limited, but is preferably 2 mass % to 20 mass %. If the contained amount of sintering aid is smaller than 2 mass %, the ceramic composite may not be sufficiently densified. On the other hand, if the contained amount of sintering aid is larger than 20 mass %, the contained amount of the silicon nitride particles 21 and the boron nitride particles 22 is reduced, and thus the average emissivity of the thermal radiation ceramic material 20 may not be sufficiently improved. From the above, the contained amount of sintering aid is desirably 2 mass % to 20 mass %.

In addition to the above components, the thermal radiation ceramic material 20 can contain various components known in the art so that a desired effect can be obtained. The amount of such components contained in the thermal radiation ceramic material 20 is not particularly limited as long as the effect of the present disclosure is not impaired.

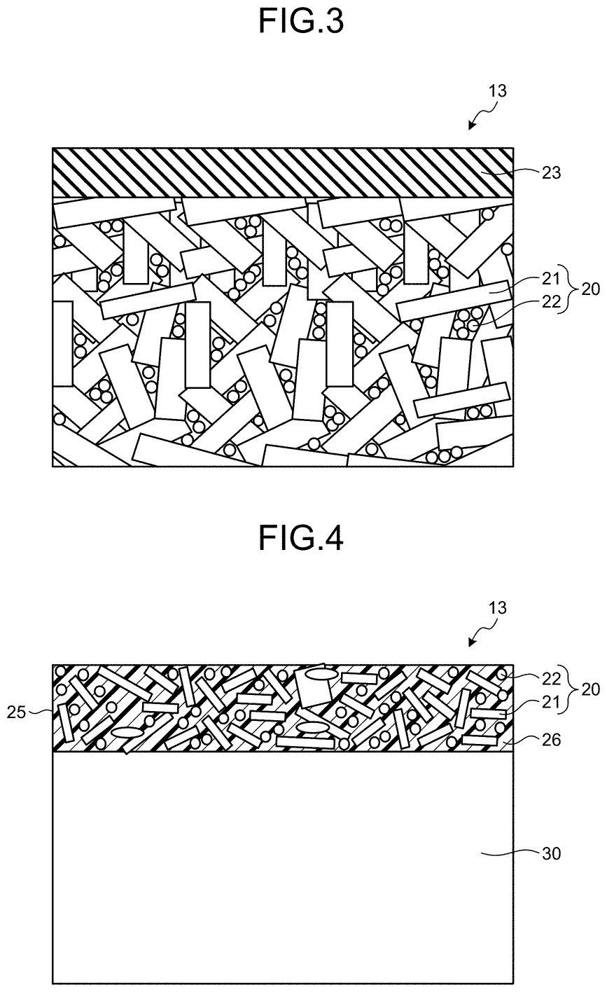

FIG. 3 is a cross-sectional view schematically illustrating another exemplary configuration of the heat dissipation member according to the first embodiment. In one example, the heat dissipation member 13 has a flat plate shape. As illustrated in FIG. 3, the heat dissipation member 13 may have a metal oxide layer 23 on the surface of at least a portion of the thermal radiation ceramic material 20. The example of FIG. 3 shows that the metal oxide layer 23 is provided on one surface of the thermal radiation ceramic material 20 having a flat plate shape. The metal oxide layer 23 has a radiation spectrum different from the radiation spectra of the silicon nitride particles 21 and the boron nitride particles 22. The metal oxide layer 23 with such a property enables a further improvement in the average emissivity of the heat dissipation member 13. In particular, the metal oxide layer 23 is preferably an oxide layer containing R₂Si₂O₇, a kind of rare-earth silicate, where R is a rare-earth element. Since R₂Si₂O₇ has a thermal expansion coefficient equivalent to that of the silicon nitride particles 21, thermal stress at the interface between the thermal radiation ceramic material 20 and the metal oxide layer 23 is prevented, contributing to preventing peeling and cracking when the thermal radiation ceramic material 20 and the metal oxide layer 23 are heated to a high temperature. Here, R₂Si₂O₇ is not particularly limited, but Y₂Si₂O₇, Lu₇Si₂O₇, or Yb₂Si₂O₇ can be used.

The metal oxide layer 23 can be formed on the surface of the thermal radiation ceramic material 20 by oxidizing the thermal radiation ceramic material 20 at high temperature in air. In this case, the amount of rare-earth oxide contained in the thermal radiation ceramic material 20 is preferably 3 mass % to 20 mass %. If the contained amount of rare-earth oxide is smaller than 3 mass %, the amount of rare-earth silicate contained in the metal oxide layer 23 is extremely reduced, and the metal oxide layer 23 may be peeled off when heated to a high temperature. On the other hand, if the contained amount of rare-earth oxide is larger than 20 mass %, the contained amount of the silicon nitride particles 21 and the boron nitride particles 22 is reduced as in the case of the above-described sintering aid, and thus the average emissivity of the thermal radiation ceramic material 20 may not be sufficiently improved. From the above, the amount of rare-earth oxide contained in the thermal radiation ceramic material 20 is desirably 3 mass % to 20 mass %.

The heat dissipation member 13 including the thermal radiation ceramic material 20 according to the first embodiment can be used as a heat dissipation measure for the electrical/electronic device 1. Specific examples of possible applications include heat sinks, heat spreaders, and heat dissipation substrates. In particular, when the heat dissipation member 13 is used as a heat sink, it is desirable that the heat sink including the heat dissipation member 13 having a flat plate shape have, on at least one side surface thereof, an uneven part with a height difference greater than or equal to the wavelength of the infrared to be emitted. Specifically, because the thermal radiation ceramic material 20 that performs thermal radiation in the wavelength regions of 3 μm to 30 μm is used, the heat sink desirably has an unevenness of 25 μm or more, more preferably an unevenness of 30 μm or more. By providing the surface with an unevenness greater than or equal to the wavelength of the infrared, the surface area effective for infrared radiation increases. Consequently, the apparent average emissivity is improved, and the cooling performance of the heat sink is improved.

Next, a method of manufacturing the heat dissipation member 13 will be described. The heat dissipation member 13 according to the first embodiment can be manufactured using a method known in the art. For example, the heat dissipation member 13 according to the first embodiment can be manufactured in the following manner.

First, silicon nitride powder, boron nitride powder, a sintering aid, a dispersant, a binding agent, and water are mixed to prepare a slurry. The average particle size of the silicon nitride powder, the boron nitride powder, and the sintering aid is not particularly limited, but is preferably less than or equal to 1 μm, more preferably less than or equal to 0.8 μm, and still more preferably less than or equal to 0.5 μm. In particular, if the average particle size of the boron nitride powder exceeds 1 μm, it may be difficult to obtain a state in which the boron nitride particles 22 are uniformly dispersed between the silicon nitride particles 21, which can cause non-uniformity in the cooling performance of the heat dissipation member 13. In addition, if the average particle size of the boron nitride powder is less than 0.05 μm, the boron nitride powder may form a strong aggregation that makes it difficult to obtain a state in which the boron nitride powder is uniformly dispersed between the silicon nitride powder. Thus, the average particle size of the boron nitride powder is 0.05 μm to 1 μm.

The dispersant is not particularly limited as long as it can be used for an aqueous slurry, and those known in the art can be used. Examples of the dispersant include: anionic surfactants such as alkyl sulfate ester salts, polyoxyethylene alkyl ether sulfate ester salts, alkyl benzene sulfonates, reactive surfactants, fatty acid salts, and naphthalene sulfonate formalin condensates; cationic surfactants such as alkylamine salts, quaternary ammonium salts, alkyl betaines which are amphoteric surfactants, and alkylamine oxides; and non-ionic surfactants such as polyoxyethylene alkyl ethers, polyoxyalkylene derivatives, sorbitan fatty acid esters, polyoxyethylene sorbitan fatty acid esters, polyoxyethylene sorbitol fatty acid esters, glycerin fatty acid esters, polyoxyethylene fatty acid esters, polyoxyethylene fatty acid castor oil, polyoxyethylene alkylamines, and alkylalkanolamides. These can be used alone or in combination of two or more.

The binding agent is not particularly limited, and those known in the art can be used. The binding agent is exemplified by an acrylic, cellulose-based, polyvinyl-alcohol-based, polyvinyl-acetal-based, urethane-based, or vinyl-acetate-based resin. These can be used alone or in combination of two or more.

The water is not particularly limited, and pure water, reverse osmosis (RO) water, deionized water, or the like can be used.

Mixing for slurry preparation is not particularly limited, and can be performed using a method known in the art. The mixing method is exemplified by the use of a kneader, a ball mill, a planetary ball mill, a kneading mixer, or a bead mill.

Next, the slurry is granulated to prepare granulated powder. The granulation method is not particularly limited, and can follow a method known in the art. For example, granulated powder can be obtained through spray drying with a spray dryer or the like. Spray drying conditions are appropriately adjusted according to the equipment to be used, and are not particularly limited.

Next, granulated powder is placed in a mold having a desired shape, and pressure molding is performed to produce a molded body. When the heat dissipation member 13 is applied to a heat sink, the desired shape is exemplified by a flat plate shape. The pressure molding method is not particularly limited, and can follow a method known in the art. Examples of the pressure molding method include cold isostatic pressing (CIP) molding, warm isostatic pressing (WIP) molding, and uniaxial pressure molding.

The pressure applied during the pressure molding is appropriately adjusted according to the type of granulated powder, the device to be used, and the like, and is not particularly limited, but is generally in the range of 30 MPa to 500 MPa.

Thereafter, the molded body is subjected to degreasing treatment. The method of the degreasing treatment is not particularly limited, and can follow a method known in the art. For example, the degreasing treatment can be performed by heating the molded body in an air atmosphere. The heating temperature is not particularly limited as long as the binding agent can be thermally decomposed, and is generally in the range of 300° C. to 800° C.

Next, the degreased body is fired. The firing method is not particularly limited, and can follow a method known in the art. For example, the degreased body is fired in a nitrogen atmosphere. The pressure of the nitrogen gas during firing may be normal pressure, but is preferably 0.2 MPa to 1.0 MPa from the viewpoint of preventing thermal decomposition of Si₃N₄. The firing temperature is not particularly limited, but is generally in the range of 1700° C. to 2100° C., preferably 1750° C. to 2050° C., and more preferably 1800° C. to 2000° C.

Thereafter, the surface of the fired body may be subjected to grinding so that the shape can be adjusted. The grinding method is not particularly limited, and can follow a method known in the art. An example of the grinding method is grinding with a diamond bit. In addition, the fired body may be subjected to heat treatment in an oxygen atmosphere. Consequently, the metal oxide layer 23 is formed on the surface. In the above-described manner, the heat dissipation member 13 according to the first embodiment is formed.

In the first embodiment, the heat dissipation member 13 includes the thermal radiation ceramic material 20 obtained by compounding the silicon nitride particles 21 and the boron nitride particles 22 having different thermal radiation spectra in the infrared regions. Consequently, the heat dissipation member 13 has a higher average emissivity in the infrared regions than the conventional ones. As a result, the heat dissipation member 13 has better cooling performance than the conventional ones.

### Second Embodiment

FIG. 4 is a cross-sectional view schematically illustrating an exemplary configuration of a heat dissipation member according to the second embodiment. Hereinafter, differences from the first embodiment will be described. Note that components identical to those in the first embodiment are denoted by the same reference signs, and the description thereof will be omitted.

The heat dissipation member 13 according to the second embodiment includes a base material 30 and a coating layer 25 containing the thermal radiation ceramic material 20. The coating layer 25 includes a filler and a binder 26. The filler is the thermal radiation ceramic material 20, which includes the silicon nitride particles 21 and the boron nitride particles 22. The ratio of the mass of the boron nitride particles 22 to the mass of the silicon nitride particles 21 and the boron nitride particles 22 in the coating layer 25 according to the second embodiment is the same as that in the thermal radiation ceramic material 20 according to the first embodiment: 10 mass % to 40 mass %.

The heat dissipation member 13, which includes the coating layer 25 containing the silicon nitride particles 21 and the boron nitride particles 22 at a predetermined mass ratio, has a higher average emissivity and better cooling performance than the conventional ones.

The binder 26 contained in the coating layer 25 is not particularly limited as long as it has a function of uniformly dispersing the silicon nitride particles 21 and the boron nitride particles 22 and fixing them as the coating layer 25. In one example, an organic binder and an inorganic binder can be appropriately selected and used as the binder 26 contained in the coating layer. One criterion for selecting the binder 26 is heat resistance. That is, the binder 26 having a desired heat resistance is appropriately selected depending on the temperature at which the heat dissipation member 13 is used.

Examples of organic binders include, but are not limited to, epoxy resins, unsaturated polyester resins, phenol resins, melamine resins, silicone resins, and polyimide resins. Among them, epoxy resins are preferable because of good adhesiveness. Examples of epoxy resins include bisphenol A epoxy resin, bisphenol F epoxy resin, o-cresol novolac epoxy resin, phenol novolac epoxy resin, alicyclic aliphatic epoxy resin, and glycidyl-aminophenol-based epoxy resin. These resins can be used alone or in combination of two or more.

When epoxy resin is used as the thermosetting resin, examples of the curing agent include: alicyclic acid anhydrides such as methyltetrahydrophthalic anhydride, methylhexahydrophthalic anhydride, and himic anhydride; aliphatic acid anhydrides such as dodecenyl succinic anhydride; aromatic acid anhydrides such as phthalic anhydride and trimellitic anhydride; organic dihydrazides such as dicyandiamide and adipic acid dihydrazide; tris (dimethylaminomethyl) phenol; dimethylbenzylamine; 1,8-diazabicyclo (5,4,0) undecene and derivatives thereof; and imidazoles such as 2-methylimidazole, 2-ethyl-4-methylimidazole, or 2-phenylimidazole. These curing agents can be used alone or in combination of two or more.

The blending amount of curing agent is appropriately set according to the thermosetting resin to be used, the type of curing agent, and the like, but in general, the blending amount of curing agent is 0.1 parts by mass to 200 parts by mass with respect to 100 parts by mass of thermosetting resin.

The coating layer 25 in the heat dissipation member 13 may contain a coupling agent from the viewpoint of improving the adhesion at the interface between the silicon nitride particles 21 and the boron nitride particles 22 and the cured product of the thermosetting resin. Examples of coupling agents include γ-glycidoxypropyltrimethoxysilane, N-β (aminoethyl) γ-aminopropyltriethoxysilane, N-phenyl-γ-aminopropyltrimethoxysilane, and γ-mercaptopropyltrimethoxysilane. These coupling agents can be used alone or in combination.

The blending amount of coupling agent is appropriately set according to the thermosetting resin to be used, the type of coupling agent, and the like. Generally, the blending amount of coupling agent is 0.01 parts by mass to 1 part by mass with respect to 100 parts by mass of thermosetting resin.

The inorganic binder is preferably the liquid binder 26 that is well compatible with the silicon nitride particles 21 and the boron nitride particles 22 and can be uniformly dispersed. Many inorganic binders have higher curing temperatures than organic binders, but from the viewpoint of workability and prevention of denaturation by heat treatment of the base material 30, the curing temperature of the inorganic binder is lower than or equal to 250° C., preferably lower than or equal to 200° C., and more preferably lower than or equal to 180° C. By using the inorganic binder with such a property, the coating layer 25 can be efficiently formed without causing thermal deterioration of the base material 30. Examples of inorganic binders include, but are not limited to, sol-gel glass, organic-inorganic hybrid glass, water glass, one-component inorganic adhesives, and two-component inorganic adhesives. These can be used alone or in combination.

The base material 30 in the heat dissipation member 13 is not particularly limited, but is preferably a metal or ceramic having high thermal conductivity from the viewpoint of efficiently transferring heat from the heat generating component 12. Examples of metals include aluminum, copper, stainless steel, iron, and other alloys. Examples of ceramics include alumina, magnesia, zirconia, aluminum nitride, and silicon carbide. These can be used alone or in combination.

In the second embodiment, the heat dissipation member 13 includes the base material 30 and the coating layer 25 containing the silicon nitride particles 21 and the boron nitride particles 22 having different thermal radiation spectra and the binder 26. This composition is advantageous in achieving a higher average thermal emissivity and better cooling performance than the conventional ones, as in the case of the first embodiment.

### EXAMPLES

Hereinafter, details of the present disclosure will be described with reference to Examples and Comparative Examples, but the present disclosure is not limited thereto.

### Example 1

The raw materials of mixed powder are silicon nitride (Si₃N₄) powder, boron nitride (BN) powder, and a sintering aid. The silicon nitride powder has an average particle size of 0.1 μm, and the boron nitride powder has an average particle size of 0.1 μm. As the sintering aid, yttria (Y₂O₃) powder having an average particle size of 1 μm, and alumina (Al₂O₃) powder having an average particle size of 1 μm are used. The blending proportion of the powders is 77 parts by mass of silicon nitride powder, 19 parts by mass of boron nitride powder, 3 parts by mass of yttria powder, and 1 part by mass of alumina powder. To 100 parts by mass of mixed powder, 1 part by mass of polyoxyethylene lauryl ether as a dispersant, 1 part by mass of polyvinyl alcohol as a binding agent, and 50 parts by mass of water are added and mixed with a ball mill for about 5 hours to prepare a slurry.

Next, the obtained slurry is spray-dried with a spray dryer to obtain granulated powder. Thereafter, the obtained granulated powder is placed in a mold having a radome shape, and CIP molding is performed using a cold isostatic pressing machine to obtain a molded body. The pressure is 98 MPa.

Subsequently, the obtained molded body is subjected to degreasing treatment by being heated at 600° C. for 2 hours in an air atmosphere. Thereafter, the degreased body is fired at 1900° C. for 2 hours in a nitrogen atmosphere. The pressure of the nitrogen gas during firing is 0.9 MPa. In this manner, the heat dissipation member 13 including the thermal radiation ceramic material 20 is formed.

### Example 2

The process is similar to that in Example 1 except that mixed powder has silicon nitride powder with a blending amount of 86 parts by mass and boron nitride powder with a blending amount of 10 parts by mass.

### Example 3

The process is similar to that in Example 1 except that mixed powder has silicon nitride powder with a blending amount of 67 parts by mass and boron nitride powder with a blending amount of 29 parts by mass.

### Example 4

The process is similar to that in Example 1 except that mixed powder has silicon nitride powder with a blending amount of 58 parts by mass and boron nitride powder with a blending amount of 38 parts by mass.

### Example 5

After being fired in a nitrogen atmosphere, the sintered body is subjected to heat treatment at 1300° C. for 1 hour in the air, that is, oxidation treatment, to form the metal oxide layer 23 on the surface of the sintered body. The other parts of the process are similar to those in Example 1.

### Example 6

Mixed powder has silicon nitride powder with a blending amount of 71 parts by mass, boron nitride powder with a blending amount of 18 parts by mass, and yttria powder with a blending amount of 10 parts by mass. After being fired in a nitrogen atmosphere, the sintered body is subjected to heat treatment at 1300° C. for 1 hour in the air, that is, oxidation treatment, to form the metal oxide layer 23 on the surface of the sintered body. The other parts of the process are similar to those in Example 1.

### Example 7

Mixed powder has silicon nitride powder with a blending amount of 67 parts by mass, boron nitride powder with a blending amount of 17 parts by mass, and yttria powder with a blending amount of 15 parts by mass. After being fired in a nitrogen atmosphere, the sintered body is subjected to heat treatment at 1300° C. for 1 hour in the air, that is, oxidation treatment, to form the metal oxide layer 23 on the surface of the sintered body. The other parts of the process are similar to those in Example 1.

### Example 8

Mixed powder has silicon nitride powder with a blending amount of 63 parts by mass, boron nitride powder with a blending amount of 16 parts by mass, and yttria powder with a blending amount of 20 parts by mass. After being fired in a nitrogen atmosphere, the sintered body is subjected to heat treatment at 1300° C. for 1 hour in the air, that is, oxidation treatment, to form the metal oxide layer 23 on the surface of the sintered body. The other parts of the process are similar to those in Example 1.

### Comparative Example 1

The process is similar to that in Example 1 except that mixed powder has silicon nitride powder with a blending amount of 96 parts by mass and boron nitride powder with a blending amount of 0 parts by mass.

### Comparative Example 2

The process is similar to that in Example 1 except that mixed powder has silicon nitride powder with a blending amount of 91 parts by mass and boron nitride powder with a blending amount of 5 parts by mass.

### Comparative Example 3

The process is similar to that in Example 1 except that mixed powder has silicon nitride powder with a blending amount of 48 parts by mass and boron nitride powder with a blending amount of 48 parts by mass.

The porosity of the heat dissipation member 13 including the thermal radiation ceramic material 20 obtained in each of Examples 1 to 8 and Comparative Examples 1 to 3 is measured. The porosity is calculated using Archimedes' principle as described above.

For the heat dissipation member 13 including the thermal radiation ceramic material 20 obtained in each of Examples 1 to 8 and Comparative Examples 1 to 3, (1) cooling performance that the heat dissipation member 13 has, (2) mechanical strength, (3) thermal conductivity, and (4) average emissivity are evaluated.

(1) Cooling Performance that the Heat Dissipation Member 13 has

A ceramic heater is attached to one side surface of the thermal radiation ceramic material 20 having a length of 100 mm, a width of 100 mm, and a thickness of 7 mm. A power of 20 W is applied to the attached ceramic heater continuously for several hours until the temperature of the thermal radiation ceramic material 20 and the ceramic heater reaches a saturation temperature. Thereafter, the surface temperature of the ceramic heater is measured using a thermocouple. The saturation temperature of the ceramic heater associated with the power input of 20 W is the cooling performance that the heat dissipation member 13 has. The lower the saturation temperature, the higher the cooling performance that the heat dissipation member 13 has.

(2) Mechanical Strength

Three-point bending strength is measured as the mechanical strength of the heat dissipation member 13. The three-point bending strength is measured using a universal testing machine. At this time, the thermal radiation ceramic material 20 is cut out into a test piece having a length of 4 mm, a width of 3 mm, and a span of 40 mm.

(3) Thermal Conductivity

Thermal conductivity is measured using a laser flash method. At this time, the thermal radiation ceramic material 20 is cut out into a test piece having a diameter of 10 mm and a thickness of 1 mm.

(4) Average Emissivity

Average emissivity is determined by measuring the emissivity in each of the wavelength regions of 3 μm to 25 μm using an emissivity measurement device, and calculating the average of the emissivity in all the wavelength regions. At this time, the thermal radiation ceramic material 20 is cut out into a test piece having a length of 20 mm, a width of 20 mm, and a thickness of 2 mm.

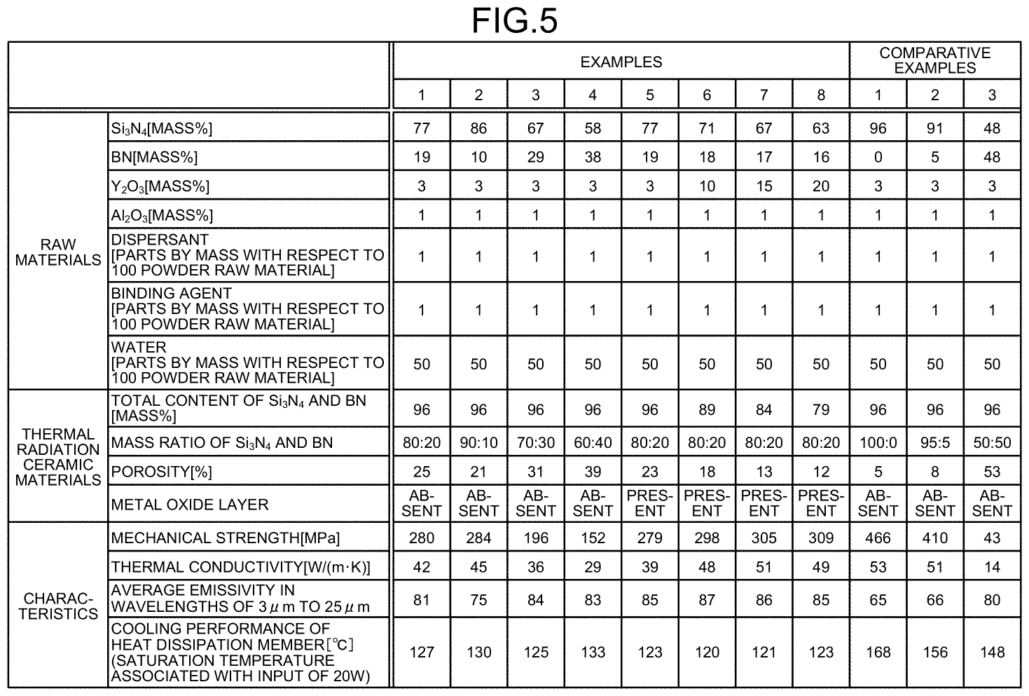

FIG. 5 is a diagram illustrating examples of the raw materials, thermal radiation ceramic materials, and characteristics of the heat dissipation members according to Examples 1 to 8 and Comparative Examples 1 to 3. The item of raw materials shows the percentage by mass of silicon nitride powder, boron nitride powder, and sintering aid constituting the powder raw material, and the parts by mass of dispersant, binding agent, and water with respect to 100 parts by mass of powder raw material. The item of the thermal radiation ceramic material 20 shows the total content of silicon nitride and boron nitride, the mass ratio of silicon nitride and boron nitride, the porosity of the thermal radiation ceramic material 20, and the presence or absence of the metal oxide layer 23. The item of characteristics shows the results of the above four evaluation items. The four evaluation items are the mechanical strength [MPa], the thermal conductivity [W/(m·K)], the average emissivity [%] of the thermal radiation ceramic material 20 in the wavelength regions of 3 μm to 25 μm, and the cooling performance that the heat dissipation member 13 has, that is, the saturation temperature [° C.] associated with the power input of 20 W.

As shown in FIG. 5, the heat dissipation members 13 of Examples 1 to 8 have a high average emissivity higher than or equal to 75%. The saturation temperature associated with the power input of 20 W is within the range of 120° C. to 133° C. The porosity of Examples 1 to 8 is in the range of 12% to 39%. The mechanical strength is in the range of 152 MPa to 309 MPa. The thermal conductivity is within the range of 29 W/(m·K) to 51 W/(m·K). The heat dissipation member 13 having the metal oxide layer 23 tends to have a higher average emissivity than the heat dissipation member 13 that does not have the metal oxide layer 23, and as a result, tends to have a lower saturation temperature associated with the power input of 20 W than the heat dissipation member 13 that does not have the metal oxide layer 23. Furthermore, Examples 1, 3, 5, 6, 7, and 8, in which the ratio of the mass of boron nitride powder to the total content of silicon nitride powder and boron nitride powder is 20 mass % to 30 mass %, have a thermal conductivity higher than 30 W/(m·K) and an average emissivity higher than 80%, that is, have high values in both thermal conductivity and average emissivity in comparison with Example 2, in which the ratio of the mass of boron nitride powder to the total content of silicon nitride powder and boron nitride powder is 10 mass %, and with Example 4, in which the ratio of the mass of boron nitride powder to the total content of silicon nitride powder and boron nitride powder is 40 mass %. Therefore, in order to improve both the emissivity and the thermal conductivity related to the cooling performance of the heat dissipation member 13, the ratio of the mass of boron nitride powder to the total content of silicon nitride powder and boron nitride powder is desirably 20 mass % to 30 mass %.

On the other hand, the heat dissipation members 13 of Comparative Examples 1 and 2 have an average emissivity of about 65%, and have a saturation temperature associated with the power input of 20 W in the range of 156° C. to 168° C. This can be because boron nitride is not contained as in Comparative Example 1, or boron nitride is contained but the contained amount of boron nitride is small as in Comparative Example 2. That is, it is considered that when Si₃N₄:BN is in the range of 90:10 to 100:0, the average emissivity is low as compared with the cases of Examples 1 to 8, and as a result, the heat dissipation member 13 has a lower cooling performance.

The heat dissipation member 13 of Comparative Example 3 has an average emissivity of about 80%, but has a saturation temperature of 148° C. associated with the power input of 20 W, which is higher than in the cases of Examples 1 to 8. This can be because the contained amount of BN is higher than in the cases of Examples 1 to 8, leading to the high porosity of 53%. That is, heat from the heating generating element is not efficiently transferred to the heat dissipation member 13, which results in an extremely low thermal conductivity as compared with the cases of Examples 1 to 8. As a result, it is considered that the heat dissipation member 13 in Comparative Example 3 has a lower cooling performance. In addition, the high porosity results in an extremely low mechanical strength, and thus, there is a high possibility that fractures or cracks occur when the heat dissipation member 13 is used.

As described above, in order for the heat dissipation member 13 to have a higher cooling performance than in Comparative Examples 1 to 3, the ratio of the mass of the boron nitride particles 22 to the mass of the silicon nitride particles 21 and the boron nitride particles 22 of the thermal radiation ceramic material 20 constituting the heat dissipation member 13 should be 10 mass % to 40 mass %. Referring to the results of Examples 1 to 8 and Comparative Examples 1 to 3, at temperatures up to 200° C., the heat dissipation member 13 that has an average emissivity higher than or equal to 70% in the wavelength regions of 3 μm to 25 μm can exhibit higher cooling performance. In this case, the porosity is preferably 10% to 40%. Furthermore, when a rare-earth oxide such as yttria powder is used as a sintering aid, the contained amount of the rare-earth oxide only needs to be 3 mass % to 20 mass %. Under these conditions, it is possible to provide the heat dissipation member 13 having a high average emissivity and good cooling performance.

The configurations described in the above-mentioned embodiments indicate examples of the contents of the present disclosure. The configurations can be combined with another well-known technique, and some of the configurations can be omitted or changed in a range not departing from the gist of the present disclosure.

### REFERENCE SIGNS LIST

1 electrical/electronic device; 10 housing; 11 substrate; 12 heat generating component; 13 heat dissipation member; 20 thermal radiation ceramic material; silicon nitride particle; 22 boron nitride particle; 23 metal oxide layer; 25 coating layer; 26 binder; 30 base material.

1. A heat dissipation member comprising a thermal radiation ceramic material, wherein
the thermal radiation ceramic material contains silicon nitride and boron nitride as main components,
a ratio of a mass of the boron nitride to a mass of the silicon nitride and the boron nitride is 10 mass % to 40 mass %,
the boron nitride has an average particle size of 0.05 μm to 1 μm, and
at temperatures up to 200° C., the thermal radiation ceramic material has an average emissivity higher than or equal to 70% in wavelength regions of 3 μm to 25 μm.

2. The heat dissipation member according to claim 1, wherein the boron nitride is hexagonal boron nitride.

3. The heat dissipation member according to claim 1, wherein the thermal radiation ceramic material is a sintered body containing silicon nitride particles and boron nitride particles.

4. The heat dissipation member according to claim 1, further comprising
a base material, wherein
the thermal radiation ceramic material is a coating layer with which a surface of the base material is coated.

5. The heat dissipation member according to claim 4, wherein the coating layer has a filler including the thermal radiation ceramic material, and a binder.

6. (canceled)

7. The heat dissipation member according to claim 1, wherein the thermal radiation ceramic material has a thermal conductivity higher than or equal to 40 W/(m·K).

8. The heat dissipation member according to claim 1, wherein the thermal radiation ceramic material contains 3 mass % to 20 mass % rare-earth oxide.

9. The heat dissipation member according to claim 1, further comprising a metal oxide layer on a part of a surface of the thermal radiation ceramic material.

10. A heat sink comprising the heat dissipation member according to claim 1.

11. The heat sink according to claim 10, wherein a surface of the heat dissipation member has an uneven part with a height difference greater than or equal to 25 μm.

12. The heat dissipation member according to claim 1, wherein the silicon nitride and the boron nitride of the thermal radiation ceramic material are uniformly dispersed.

13. The heat dissipation member according to claim 1, wherein the heat dissipation member does not contain resin.

14. The heat dissipation member according to claim 9, wherein the metal oxide layer is a rare-earth silicate represented by R₂Si₂O₇, where R is a rare-earth element.

15. The heat dissipation member according to claim 9, wherein the metal oxide layer is a layer formed on the surface of the thermal radiation ceramic material by oxidizing the thermal radiation ceramic material at high temperature in air.
